(19) United States
(12) Patent Application Publication
(10) Pub. No.: US 2026/0351323 A1
(43) Pub. Date: Nov. 5, 2026

(54) ADAPTIVE DYNAMIC SENSE TIME BASED ON UNSELECTED SUB-BLOCK OPENNESS TO COMPENSATE THRESHOLD VOLTAGE DISTRIBUTION WIDENING

(71) Applicant: Sandisk Technologies, Inc., Milpitas, CA (US)

(72) Inventors: Jiacen Guo, Cupertino, CA (US); Xiang Yang, Santa Clara, CA (US)

(21) Appl. No.: 19/196,840

(22) Filed: May 2, 2025

(51) Int. Cl. G11C 16/34; G11C 11/56; G11C 16/04; G11C 16/10

(52) U.S. Cl. CPC G11C 16/3459; G11C 11/5628; G11C 11/5671; G11C 16/0483; G11C 16/10

(57) ABSTRACT

A memory apparatus includes memory cells connected to word lines and configured to retain a threshold voltage. The memory cells are disposed in memory holes defining channels and extending vertically through a stack of the word lines. The memory cells form a first sub-block and a second sub-block vertically arranged. A control means applies a series of programming pulses each followed by verification pulses to ones of the word lines of a selected one of the first sub-block or the second sub-block to program and verify the memory cells connected thereto during a program operation. A channel current flowing through the channels and sensed for a sense time is indicative of the threshold voltage of the memory cell being verified. The control means adjusts the sense time based on an amount of the memory cells of an unselected one of the first sub-block or the second sub-block already programmed.

### FIELD

This application relates to non-volatile memory apparatuses and the operation of non-volatile memory apparatuses.

### BACKGROUND

This section provides background information related to the technology associated with the present disclosure and, as such, is not necessarily prior art.

Semiconductor memory is widely used in various electronic devices, such as cellular telephones, digital cameras, personal digital assistants, medical electronics, mobile computing devices, servers, solid state drives, non-mobile computing devices and other devices. Semiconductor memory may comprise non-volatile memory or volatile memory. A non-volatile memory allows information to be stored and retained even when the non-volatile memory is not connected to a source of power, e.g., a battery. Such non-volatile memory devices may include a plurality of memory cells that are arranged in an array which includes a plurality of word lines.

During a program verify operation, the threshold voltage (“Vt”) of a memory cell can be determined by controlling the time it takes for the sense node to discharge through a bit line coupled to the memory cell. Therefore, the Vt is the function of the discharging time, the longer of the discharging time, the smaller of the determined Vt. Some current schemes use two different sense times to determine the memory cell behavior. For example, a verify high (“VH”) voltage may define the desired, final Vt of the memory cell once programming has been completed, while a verify low (“VL”) voltage may correspond with a Vt where programming is slowed in a process known as quick pass write (“QPW”) to allow for more accurate programming.

The memory cells can be grouped into blocks that may be divided into sub-blocks. However, depending on the amount of memory cells of the sub-blocks that are programmed (i.e., closed) or still in the erase state (i.e., open), a width of threshold voltage distributions of the memory cells being programmed may be adversely affected. Thus, improved memory apparatuses and methods of operation are desired.

### SUMMARY

This section provides a general summary of the present disclosure and is not a comprehensive disclosure of its full scope or all of its features and advantages.

An object of the present disclosure is to provide a memory apparatus and a method of operation of the memory apparatus that address and overcome shortcomings described herein.

Accordingly, it is an aspect of the present disclosure to provide a memory apparatus including memory cells each connected to one of a plurality of word lines and configured to retain a threshold voltage corresponding to one of a plurality of data states. The memory cells are disposed in memory holes defining channels and extending vertically through a stack of the plurality of word lines. Each of the memory holes is coupled to one of a plurality of bit lines. The memory cells form a block including a first sub-block and a second sub-block disposed vertically above the first sub-block. The memory apparatus also includes a control means configured to apply each of a series of programming pulses of a program voltage followed by verification pulses of a plurality of program verify voltages each associated with one of the plurality of data states to selected ones of the plurality of word lines of a selected one of the first sub-block or the second sub-block to program and verify the memory cells connected thereto during each of a plurality of program loops of a program operation. A channel current flowing through the channels of the memory holes and sensed via the plurality of bit lines connected thereto for a sense time is indicative of the threshold voltage of the memory cell being verified during each of the verification pulses. The control means is also configured to adjust the sense time based on an amount of the memory cells of an unselected one of the first sub-block or the second sub-block that are already programmed.

According to another aspect of the disclosure, a controller in communication with a memory apparatus including memory cells each connected to one of a plurality of word lines is provided. The memory cells are configured to retain a threshold voltage corresponding to one of a plurality of data states. The memory cells are disposed in memory holes defining channels and extending vertically through a stack of the plurality of word lines. Each of the memory holes is coupled to one of a plurality of bit lines. The memory cells form a block including a first sub-block and a second sub-block disposed vertically above the first sub-block. The controller is configured to instruct the memory apparatus to instruct the memory apparatus to apply each of a series of programming pulses of a program voltage followed by verification pulses of a plurality of program verify voltages each associated with one of the plurality of data states to selected ones of the plurality of word lines of a selected one of the first sub-block or the second sub-block to program and verify the memory cells connected thereto during each of a plurality of program loops of a program operation. A channel current flowing through the channels of the memory holes and sensed via the plurality of bit lines connected thereto for a sense time is indicative of the threshold voltage of the memory cell being verified during each of the verification pulses. The controller is also configured to instruct the memory apparatus to adjust the sense time based on an amount of the memory cells of an unselected one of the first sub-block or the second sub-block that are already programmed.

According to an additional aspect of the disclosure, a method of operating a memory apparatus is provided. The memory apparatus includes memory cells each connected to one of a plurality of word lines and configured to retain a threshold voltage corresponding to one of a plurality of data states. The memory cells are disposed in memory holes defining channels and extending vertically through a stack of the plurality of word lines. Each of the memory holes is coupled to one of a plurality of bit lines. The memory cells form a block including a first sub-block and a second sub-block disposed vertically above the first sub-block. The method includes the step of applying each of a series of programming pulses of a program voltage followed by verification pulses of a plurality of program verify voltages each associated with one of the plurality of data states to selected ones of the plurality of word lines of a selected one of the first sub-block or the second sub-block to program and verify the memory cells connected thereto during each of a plurality of program loops of a program operation. A channel current flowing through the channels of the memory holes and sensed via the plurality of bit lines connected thereto for a sense time is indicative of the threshold voltage of the memory cell being verified during each of the verification pulses. The method also includes the step of adjusting the sense time based on an amount of the memory cells of an unselected one of the first sub-block or the second sub-block that are already programmed.

Further areas of applicability will become apparent from the description provided herein. The description and specific examples in this summary are intended for purposes of illustration only and are not intended to limit the scope of the present disclosure.

### BRIEF DESCRIPTION OF THE DRAWINGS

For a detailed description of example embodiments, reference will now be made to the accompanying drawings in which:

FIG. 1A is a block diagram of an example memory device according to aspects of the disclosure;

FIG. 1B is a block diagram of an example control circuit that includes a programming circuit, a counting circuit, and a determination circuit according to aspects of the disclosure;

FIG. 2 illustrates schematic views of three types of memory architectures utilizing staggered memory strings according to aspects of the disclosure;

FIG. 3A illustrates a cross-sectional view of example floating gate memory cells in NAND strings according to aspects of the disclosure;

FIG. 3B illustrates a cross-sectional view along a contact line shown in FIG. 3A according to aspects of the disclosure;

FIGS. 4A and 4B illustrate non-volatile memory in which a charge-trapping memory cell uses a non-conductive dielectric material in place of a conductive floating gate to store charge in a non-volatile manner according to aspects of the disclosure;

FIG. 5 illustrates an example block diagram of the sense block of FIG. 1A according to aspects of the disclosure;

FIG. 6A is a perspective view of a set of blocks in an example three-dimensional configuration of the memory array of FIG. 1A according to aspects of the disclosure;

FIG. 6B illustrates an example cross-sectional view of a portion of one of the blocks of FIG. 6A according to aspects of the disclosure;

FIG. 6C illustrates a plot of memory hole diameter in the stack of FIG. 6B according to aspects of the disclosure;

FIG. 6D illustrates a close-up view of the region of the stack of FIG. 6B according to aspects of the disclosure;

FIG. 6E depicts an example set of threshold voltage distributions for an eight-state memory device in which each storage element stores three bits of data according to aspects of the disclosure;

FIG. 7A depicts the threshold voltages of a memory cell during programming where there is too small of a voltage gap between verify low VL and verify high VH according to aspects of the disclosure;

FIG. 7B depicts the threshold voltages of a memory cell during programming where there is too large of a voltage gap between verify low VL and verify high VH according to aspects of the disclosure;

FIG. 8A depicts the threshold voltages of a memory cell during programming according to aspects of the disclosure;

FIG. 8B depicts the Vpgm voltages during the same programming operation of FIG. 8A according to aspects of the disclosure;

FIG. 8C depicts the bit line voltages applied during the same programming operation of FIGS. 8A and 8B according to aspects of the disclosure;

FIG. 9 shows two example sub-blocks with different amounts of the memory cells programmed according to aspects of the disclosure;

FIG. 10 shows two example sub-blocks with different amounts of the memory cells programmed along with a later read operation of one of the sub-blocks when the memory cells of both sub-blocks are completely programmed according to aspects of the disclosure;

FIG. 11 shows a plot of threshold voltage distributions for an example data state for the cases shown in FIGS. 9 and 10 according to aspects of the disclosure;

FIG. 12 shows the cases involving programming the two example sub-blocks with different amounts of the memory cells programmed of FIGS. 9 and 10 along with two cases of a later read operation of one of the sub-blocks with the memory cells of the first sub-block all programmed and all erased while the memory cells of the second sub-block are all programmed according to aspects of the disclosure;

FIG. 13 shows an equivalent circuit diagrams of memory holes for the two programming cases of FIG. 12 according to aspects of the disclosure;

FIG. 14 is a plot of drain current versus gate voltage during the verify portion or verify operation of a program operation for an example memory cell according to aspects of the disclosure;

FIG. 15 shows plots of the threshold voltage with and without over programming according to aspects of the disclosure;

FIG. 16 is a plot of a sensed voltage versus time during a verify operation without adjusting the sense time as described herein according to aspects of the disclosure;

FIG. 17 shows plots of the threshold voltage distribution when the unselected sub-block is fully closed, partially open, and fully open with no adjustment of the sense time and illustrates over programming according to aspects of the disclosure;

FIG. 18 is an example table with the plurality of predetermined sense times for each of the plurality of predetermined magnitudes of the openness of the unselected one of the first sub-block or the second sub-block and based on the one plurality of data states targeted for the memory cells being verified according to aspects of the disclosure;

FIG. 19 is a plot of a sensed voltage versus time during a verify operation with the adjustment of the sense time as described herein according to aspects of the disclosure;

FIG. 20 shows plots of the threshold voltage distribution when the unselected sub-block is fully closed, partially open, and fully open using the adjustment of the sense time as described herein and illustrates no over programming according to aspects of the disclosure; and

FIG. 21 illustrates steps of a method of operating a memory apparatus according to aspects of the disclosure.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

In the following description, details are set forth to provide an understanding of the present disclosure. In some instances, certain circuits, structures and techniques have not been described or shown in detail in order not to obscure the disclosure.

In general, the present disclosure relates to non-volatile memory apparatuses of the type well-suited for use in many applications. The non-volatile memory apparatus and associated methods of forming of this disclosure will be described in conjunction with one or more example embodiments. However, the specific example embodiments disclosed are merely provided to describe the inventive concepts, features, advantages and objectives with sufficient clarity to permit those skilled in this art to understand and practice the disclosure. Specifically, the example embodiments are provided so that this disclosure will be thorough, and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

Various terms are used to refer to particular system components. Different companies may refer to a component by different names-this document does not intend to distinguish between components that differ in name but not function. In the following discussion and in the claims, the terms “including” and “comprising” are used in an open-ended fashion, and thus should be interpreted to mean “including, but not limited to . . . .” Also, the term “couple” or “couples” is intended to mean either an indirect or direct connection. Thus, if a first device couples to a second device, that connection may be through a direct connection or through an indirect connection via other devices and connections.

Additionally, when a layer or element is referred to as being “on” another layer or substrate, in can be directly on the other layer of substrate, or intervening layers may also be present. Further, it will be understood that when a layer is referred to as being “under” another layer, it can be directly under, and one or more intervening layers may also be present. Furthermore, when a layer is referred to as “between” two layers, it can be the only layer between the two layers, or one or more intervening layers may also be present.

For purposes of this document, reference in the specification to “an embodiment,” “one embodiment,” “some embodiments,” or “another embodiment” may be used to describe different embodiments or the same embodiment.

For purposes of this document, the term “based on” may be read as “based at least in part on.”

For purposes of this document, without additional context, use of numerical terms such as a “first” object, a “second” object, and a “third” object may not imply an ordering of objects, but may instead be used for identification purposes to identify different objects.

For purposes of this document, the term “set” of objects may refer to a “set” of one or more of the objects.

As described, non-volatile memory systems are a type of memory that retains stored information without requiring an external power source. Non-volatile memory is widely used in various electronic devices and in stand-alone memory devices. For example, non-volatile memory can be found in laptops, digital audio player, digital cameras, smart phones, video games, scientific instruments, industrial robots, medical electronics, solid-state drives, USB drives, memory cards, and the like. Non-volatile memory can be electronically programmed/reprogrammed and erased.

Examples of non-volatile memory systems include flash memory, such as NAND flash or NOR flash. NAND flash memory structures typically arrange multiple memory cell transistors (e.g., floating-gate transistors or charge trap transistors) in series with and between two select gates (e.g., a drain-side select gate and a source-side select gate). The memory cell transistors in series and the select gates may be referred to as a NAND string. NAND flash memory may be scaled in order to reduce cost per bit.

A programming operation for a set of memory cells of a memory device typically involves applying a series of program voltages to the memory cells after the memory cells are provided in an erased state. Each program voltage is provided in a program loop, also referred to as a program-verify iteration. For example, the program voltage may be applied to a word line which is connected to control gates of the memory cells. In one approach, incremental step pulse programming is performed, where the program voltage is increased by a step size in each program loop. Verify operations may be performed after each program voltage to determine whether the memory cells have completed programming. When programming is completed for a memory cell, it can be locked out from further programming while programming continues for other memory cells in subsequent program loops.

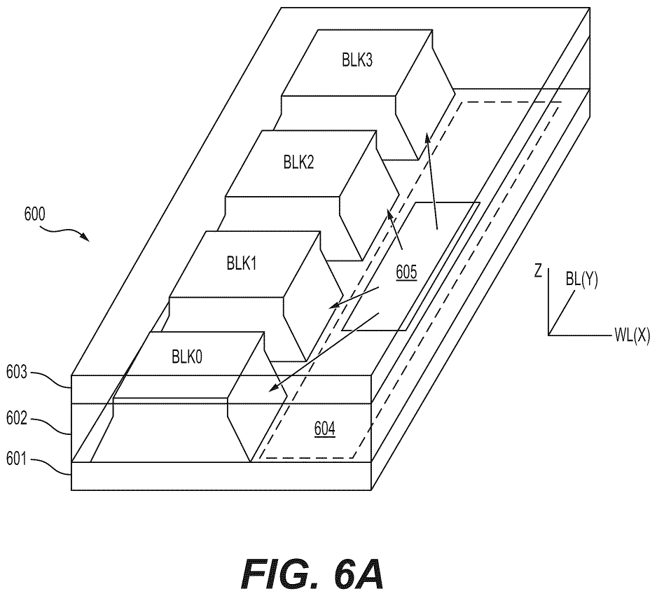

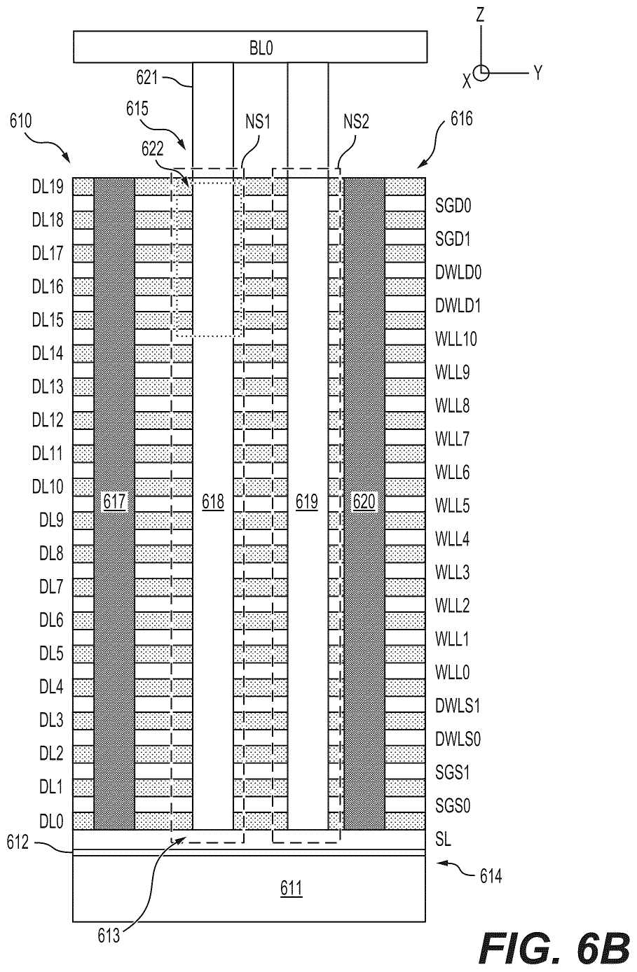

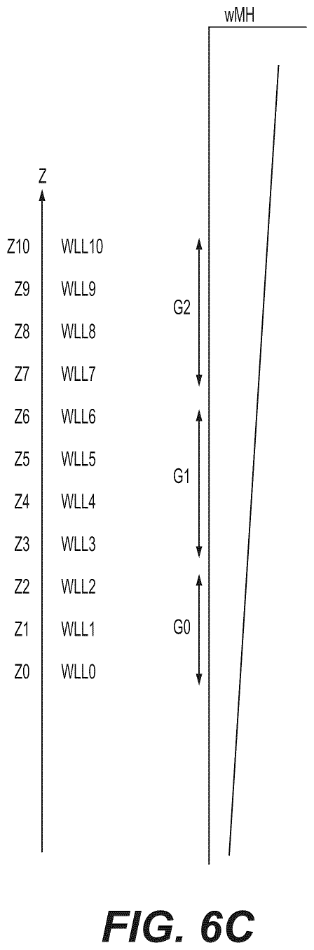

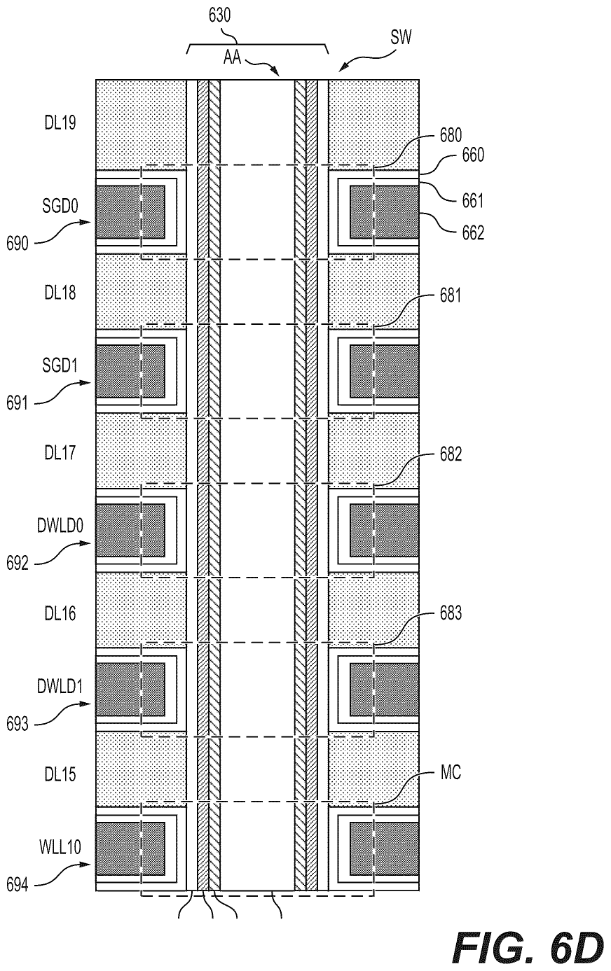

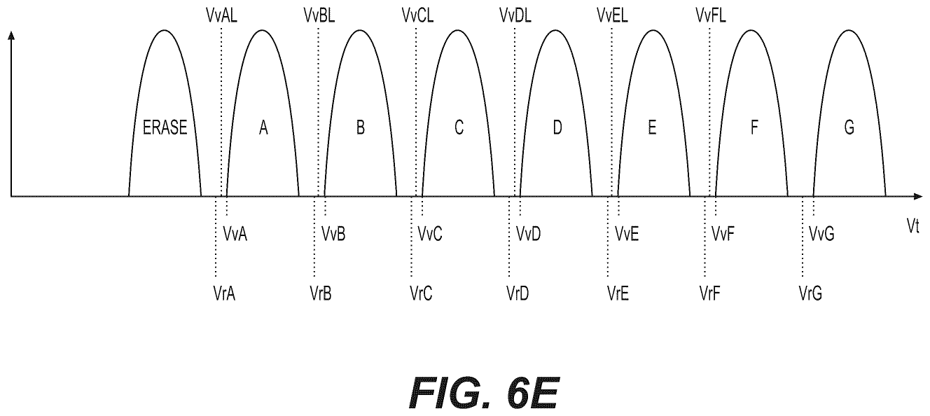

Each memory cell may be associated with a data state according to write data in a program command. Based on its data state, a memory cell will either remain in the erased state or be programmed to a data state (a programmed data state) different from the erased state. For example, in a one-bit per cell memory device (single-level cell (SLC)), there are two data states including the erased state and one higher data state. In a two-bit per cell memory device (multi-level cell (MLC)), there are four data states including the erased state and three higher data states referred to as the A, B and C data states. In a three-bit per cell memory device (triple-level cell (TLC)), there are eight data states including the erased state and seven higher data states referred to as the A, B, C, D, E, F and G data states (see e.g., FIG. 6E). In a four-bit per cell memory device (quad-level cell (QLC)), there are sixteen data states including the erased state and fifteen higher data states referred to as the Er, S1, S2, S3, S4, S5, S6, S7, S8, S9, S10, S11, S12, S13, S14, S15 data states. Each memory cell may store a data state (e.g., a binary value) and is programmed to a threshold voltage state corresponding to the data state. Each state represents a different value and is assigned a voltage window including a range of possible threshold voltages.

During the verify operations, the threshold voltage of each of the memory cells is sensed in a read operation in which a current flowing through a channel defined by a memory hole associated with the memory cell can be equated to the threshold voltage of the memory cell. In a 3D NAND structure, a block of the memory cells may be formed into tiers, separated by a joint region and operable as sub-blocks. An amount of the memory cells are programmed in each of these sub-blocks during programming and later during a read operation can cause variation in the threshold voltage distribution for the memory cells.

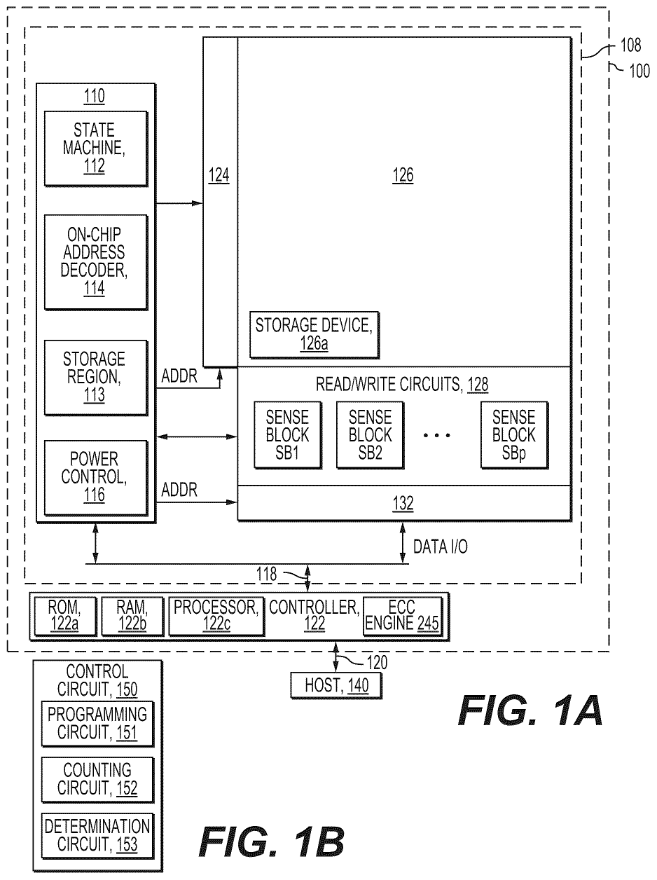

FIG. 1A is a block diagram of an example memory device. The memory device 100 may include one or more memory die 108. The memory die 108 includes a memory structure 126 of memory cells, such as an array of memory cells, control circuitry 110, and read/write circuits 128. The memory structure 126 is addressable by word lines via a row decoder 124 and by bit lines via a column decoder 132. The read/write circuits 128 include multiple sense blocks SB1, SB2, . . . SBp (sensing circuitry) and allow a page of memory cells to be read or programmed in parallel. Typically, a controller 122 is included in the same memory device 100 (e.g., a removable storage card) as the one or more memory die 108. Commands and data are transferred between the host 140 and controller 122 via a data bus 120, and between the controller and the one or more memory die 108 via lines 118.

The memory structure 126 can be two-dimensional or three-dimensional. The memory structure 126 may comprise one or more array of memory cells including a three-dimensional array. The memory structure 126 may comprise a monolithic three-dimensional memory structure in which multiple memory levels are formed above (and not in) a single substrate, such as a wafer, with no intervening substrates. The memory structure 126 may comprise any type of non-volatile memory that is monolithically formed in one or more physical levels of arrays of memory cells having an active area disposed above a silicon substrate. The memory structure 126 may be in a non-volatile memory device having circuitry associated with the operation of the memory cells, whether the associated circuitry is above or within the substrate.

The control circuitry 110 cooperates with the read/write circuits 128 to perform memory operations on the memory structure 126, and includes a state machine 112, an on-chip address decoder 114, and a power control module 116. The state machine 112 provides chip-level control of memory operations.

A storage region 113 may, for example, be provided for programming parameters. The programming parameters may include a program voltage, a program voltage bias, position parameters indicating positions of memory cells, contact line connector thickness parameters, a verify voltage, and/or the like. The position parameters may indicate a position of a memory cell within the entire array of NAND strings, a position of a memory cell as being within a particular NAND string group, a position of a memory cell on a particular plane, and/or the like. The contact line connector thickness parameters may indicate a thickness of a contact line connector, a substrate or material that the contact line connector is comprised of, and/or the like.

The on-chip address decoder 114 provides an address interface between that used by the host or a memory controller to the hardware address used by the decoders 124 and 132. The power control module 116 controls the power and voltages supplied to the word lines and bit lines during memory operations. It can include drivers for word lines, SGS and SGD transistors, and source lines. The sense blocks can include bit line drivers, in one approach. An SGS transistor is a select gate transistor at a source end of a NAND string, and an SGD transistor is a select gate transistor at a drain end of a NAND string.

In some embodiments, some of the components can be combined. In various designs, one or more of the components (alone or in combination), other than memory structure 126, can be thought of as at least one control circuit which is configured to perform the actions described herein. For example, a control circuit may include any one of, or a combination of, control circuitry 110, state machine 112, decoders 114/132, power control module 116, sense blocks SBb, SB2, . . . , SBp, read/write circuits 128, controller 122, and so forth.

The control circuits can include a programming circuit configured to perform a program and verify operation for one set of memory cells, wherein the one set of memory cells comprises memory cells assigned to represent one data state among a plurality of data states and memory cells assigned to represent another data state among the plurality of data states; the program and verify operation comprising a plurality of program and verify iterations; and in each program and verify iteration, the programming circuit performs programming for the one word line after which the programming circuit applies a verification signal to the one word line. The control circuits can also include a counting circuit configured to obtain a count of memory cells which pass a verify test for the one data state. The control circuits can also include a determination circuit configured to determine, based on an amount by which the count exceeds a threshold, a particular program and verify iteration among the plurality of program and verify iterations in which to perform a verify test for another data state for the memory cells assigned to represent another data state.

For example, FIG. 1B is a block diagram of an example control circuit 150 which comprises a programming circuit 151, a counting circuit 152, and a determination circuit 153.

The off-chip controller 122 may comprise a processor 122c, storage devices (memory) such as ROM 122a and RAM 122b and an error-correction code (ECC) engine 245. The ECC engine can correct a number of read errors which are caused when the upper tail of a Vth distribution becomes too high. However, uncorrectable errors may exist in some cases. The techniques provided herein reduce the likelihood of uncorrectable errors.

The storage device(s) 122a, 122b comprise, code such as a set of instructions, and the processor 122c is operable to execute the set of instructions to provide the functionality described herein. Alternately or additionally, the processor 122c can access code from a storage device 126 a of the memory structure 126, such as a reserved area of memory cells in one or more word lines. For example, code can be used by the controller 122 to access the memory structure 126 such as for programming, read and erase operations. The code can include boot code and control code (e.g., set of instructions). The boot code is software that initializes the controller 122 during a booting or startup process and enables the controller 122 to access the memory structure 126. The code can be used by the controller 122 to control one or more memory structures 126. Upon being powered up, the processor 122c fetches the boot code from the ROM 122a or storage device 126a for execution, and the boot code initializes the system components and loads the control code into the RAM 122b. Once the control code is loaded into the RAM 122b, it is executed by the processor 122c. The control code includes drivers to perform basic tasks such as controlling and allocating memory, prioritizing the processing of instructions, and controlling input and output ports.

Generally, the control code can include instructions to perform the functions described herein including the steps of the flowcharts discussed further below and provide the voltage waveforms including those discussed further below.

In one embodiment, the host is a computing device (e.g., laptop, desktop, smartphone, tablet, digital camera) that includes one or more processors, one or more processor readable storage devices (RAM, ROM, flash memory, hard disk drive, solid state memory) that store processor readable code (e.g., software) for programming the one or more processors to perform the methods described herein. The host may also include additional system memory, one or more input/output interfaces and/or one or more input/output devices in communication with the one or more processors.

Other types of non-volatile memory in addition to NAND flash memory can also be used.

Semiconductor memory devices include volatile memory devices, such as dynamic random access memory (“DRAM”) or static random access memory (“SRAM”) devices, non-volatile memory devices, such as resistive random access memory (“ReRAM”), electrically erasable programmable read only memory (“EEPROM”), flash memory (which can also be considered a subset of EEPROM), ferroelectric random access memory (“FRAM”), and magnetoresistive random access memory (“MRAM”), and other semiconductor elements capable of storing information. Each type of memory device may have different configurations. For example, flash memory devices may be configured in a NAND or a NOR configuration.

The memory devices can be formed from passive and/or active elements, in any combinations. By way of non-limiting example, passive semiconductor memory elements include ReRAM device elements, which in some embodiments include a resistivity switching storage element, such as an anti-fuse or phase change material, and optionally a steering element, such as a diode or transistor. Further by way of non-limiting example, active semiconductor memory elements include EEPROM and flash memory device elements, which in some embodiments include elements containing a charge storage region, such as a floating gate, conductive nanoparticles, or a charge storage dielectric material.

Multiple memory elements may be configured so that they are connected in series or so that each element is individually accessible. By way of non-limiting example, flash memory devices in a NAND configuration (NAND memory) typically contain memory elements connected in series. A NAND string is an example of a set of series-connected transistors comprising memory cells and SG transistors.

A NAND memory array may be configured so that the array is composed of multiple memory strings in which a string is composed of multiple memory elements sharing a single bit line and accessed as a group. Alternatively, memory elements may be configured so that each element is individually accessible, e.g., a NOR memory array. NAND and NOR memory configurations are examples, and memory elements may be otherwise configured. The semiconductor memory elements located within and/or over a substrate may be arranged in two or three dimensions, such as a two-dimensional memory structure or a three-dimensional memory structure.

In a two-dimensional memory structure, the semiconductor memory elements are arranged in a single plane or a single memory device level. Typically, in a two-dimensional memory structure, memory elements are arranged in a plane (e.g., in an x-y direction plane) which extends substantially parallel to a major surface of a substrate that supports the memory elements. The substrate may be a wafer over or in which the layer of the memory elements is formed or it may be a carrier substrate which is attached to the memory elements after they are formed. As a non-limiting example, the substrate may include a semiconductor such as silicon.

The memory elements may be arranged in the single memory device level in an ordered array, such as in a plurality of rows and/or columns. However, the memory elements may be arrayed in non-regular or non-orthogonal configurations. The memory elements may each have two or more electrodes or contact lines, such as bit lines and word lines.

A three-dimensional memory array is arranged so that memory elements occupy multiple planes or multiple memory device levels, thereby forming a structure in three dimensions (i.e., in the x, y and z directions, where the z-direction is substantially perpendicular and the x-and y-directions are substantially parallel to the major surface of the substrate).

As a non-limiting example, a three-dimensional memory structure may be vertically arranged as a stack of multiple two-dimensional memory device levels. As another non-limiting example, a three-dimensional memory array may be arranged as multiple vertical columns (e.g., columns extending substantially perpendicular to the major surface of the substrate, i.e., in the y direction) with each column having multiple memory elements. The columns may be arranged in a two-dimensional configuration, e.g., in an x-y plane, resulting in a three-dimensional arrangement of memory elements with elements on multiple vertically stacked memory planes. Other configurations of memory elements in three dimensions can also constitute a three-dimensional memory array.

By way of non-limiting example, in a three-dimensional array of NAND strings, the memory elements may be coupled together to form a NAND string within a single horizontal (e.g., x-y) memory device level. Alternatively, the memory elements may be coupled together to form a vertical NAND string that traverses across multiple horizontal memory device levels. Other three-dimensional configurations can be envisioned wherein some NAND strings contain memory elements in a single memory level while other strings contain memory elements which span through multiple memory levels. Three-dimensional memory arrays may also be designed in a NOR configuration and in a ReRAM configuration.

Typically, in a monolithic three-dimensional memory array, one or more memory device levels are formed above a single substrate. Optionally, the monolithic three-dimensional memory array may also have one or more memory layers at least partially within the single substrate. As a non-limiting example, the substrate may include a semiconductor such as silicon. In a monolithic three-dimensional array, the layers constituting each memory device level of the array are typically formed on the layers of the underlying memory device levels of the array. However, layers of adjacent memory device levels of a monolithic three-dimensional memory array may be shared or have intervening layers between memory device levels.

Then again, two-dimensional arrays may be formed separately and then packaged together to form a non-monolithic memory device having multiple layers of memory. For example, non-monolithic stacked memories can be constructed by forming memory levels on separate substrates and then stacking the memory levels atop each other. The substrates may be thinned or removed from the memory device levels before stacking, but as the memory device levels are initially formed over separate substrates, the resulting memory arrays are not monolithic three-dimensional memory arrays. Further, multiple two-dimensional memory arrays or three-dimensional memory arrays (monolithic or non-monolithic) may be formed on separate chips and then packaged together to form a stacked-chip memory device.

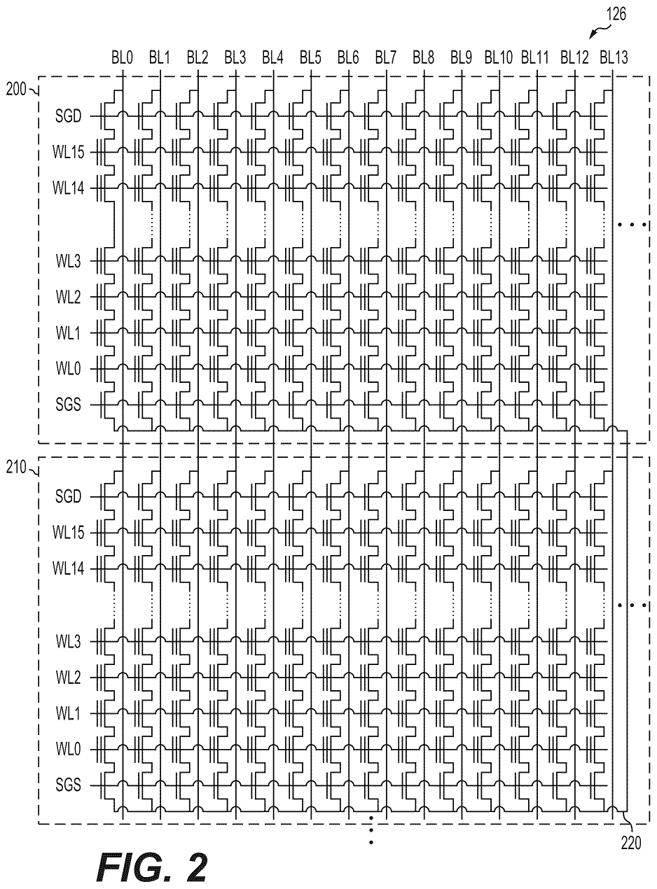

FIG. 2 illustrates schematic views of three types of memory architectures utilizing staggered memory strings. For example, reference number 201 shows a schematic view of a first example memory architecture, reference number 203 shows a schematic view of a second example memory architecture, and reference number 205 shows a schematic view of a third example memory architecture. In some embodiments, as shown, the memory architecture may include an array of staggered NAND strings.

FIG. 2 illustrates blocks 200, 210 of memory cells in an example two-dimensional configuration of the memory array 126 of FIG. 1A. The memory array 126 can include many such blocks 200, 210. Each example block 200, 210 includes a number of NAND strings and respective bit lines, e.g., BL0, BL1, . . . which are shared among the blocks. Each NAND string is connected at one end to a drain-side select gate (SGD), and the control gates of the drain select gates are connected via a common SGD line. The NAND strings are connected at their other end to a source-side select gate (SGS) which, in turn, is connected to a common source line 220. Sixteen word lines, for example, WL0-WL15, extend between the SGSs and the SGDs. In some cases, dummy word lines, which contain no user data, can also be used in the memory array adjacent to the select gate transistors. Such dummy word lines can shield the edge data word line from certain edge effects.

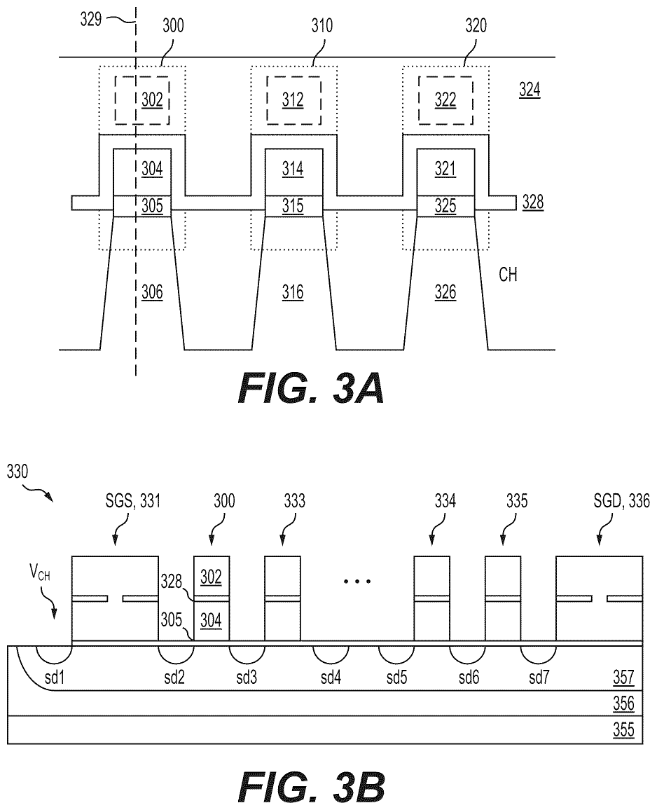

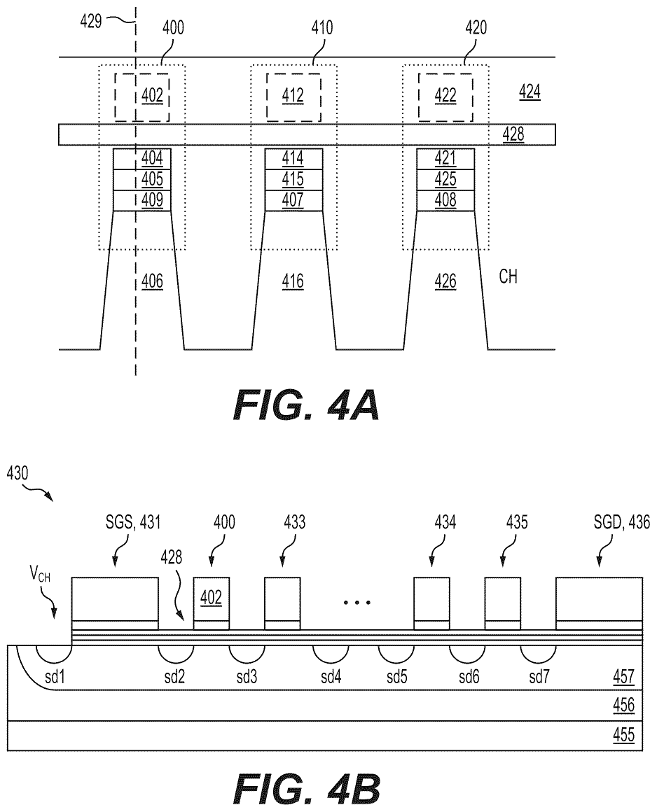

One type of non-volatile memory which may be provided in the memory array is a floating gate memory, such as of the type shown in FIGS. 3A and 3B. However, other types of non-volatile memory can also be used. As discussed in further detail below, in another example shown in FIGS. 4A and 4B, a charge-trapping memory cell uses a non-conductive dielectric material in place of a conductive floating gate to store charge in a non-volatile manner. A triple layer dielectric formed of silicon oxide, silicon nitride and silicon oxide (“ONO”) is sandwiched between a conductive control gate and a surface of a semi-conductive substrate above the memory cell channel. The cell is programmed by injecting electrons from the cell channel into the nitride, where they are trapped and stored in a limited region. This stored charge then changes the threshold voltage of a portion of the channel of the cell in a manner that is detectable. The cell is erased by injecting hot holes into the nitride. A similar cell can be provided in a split-gate configuration where a doped polysilicon gate extends over a portion of the memory cell channel to form a separate select transistor.

In another approach, NROM cells are used. Two bits, for example, are stored in each NROM cell, where an ONO dielectric layer extends across the channel between source and drain diffusions. The charge for one data bit is localized in the dielectric layer adjacent to the drain, and the charge for the other data bit localized in the dielectric layer adjacent to the source. Multi-state data storage is obtained by separately reading binary states of the spatially separated charge storage regions within the dielectric. Other types of non-volatile memory are also known.

FIG. 3A illustrates a cross-sectional view of example floating gate memory cells 300, 310, 320 in NAND strings. In this Figure, a bit line or NAND string direction goes into the page, and a word line direction goes from left to right. As an example, word line 324 extends across NAND strings which include respective channel regions 306, 316 and 326. The memory cell 300 includes a control gate 302, a floating gate 304, a tunnel oxide layer 305 and the channel region 306. The memory cell 310 includes a control gate 312, a floating gate 314, a tunnel oxide layer 315 and the channel region 316. The memory cell 320 includes a control gate 322, a floating gate 321, a tunnel oxide layer 325 and the channel region 326. Each memory cell 300, 310, 320 is in a different respective NAND string. An inter-poly dielectric (IPD) layer 328 is also illustrated. The control gates 302, 312, 322 are portions of the word line. A cross-sectional view along contact line connector 329 is provided in FIG. 3B.

The control gate 302, 312, 322 wraps around the floating gate 304, 314, 321, increasing the surface contact area between the control gate 302, 312, 322 and floating gate 304, 314, 321. This results in higher IPD capacitance, leading to a higher coupling ratio which makes programming and erase easier. However, as NAND memory devices are scaled down, the spacing between neighboring cells 300, 310, 320 becomes smaller so there is almost no space for the control gate 302, 312, 322 and the IPD layer 328 between two adjacent floating gates 302, 312, 322.

As an alternative, as shown in FIGS. 4A and 4B, the flat or planar memory cell 400, 410, 420 has been developed in which the control gate 402, 412, 422 is flat or planar; that is, it does not wrap around the floating gate and its only contact with the charge storage layer 428 is from above it. In this case, there is no advantage in having a tall floating gate. Instead, the floating gate is made much thinner. Further, the floating gate can be used to store charge, or a thin charge trap layer can be used to trap charge. This approach can avoid the issue of ballistic electron transport, where an electron can travel through the floating gate after tunneling through the tunnel oxide during programming.

FIG. 4A depicts a cross-sectional view of example charge-trapping memory cells 400, 410, 420 in NAND strings. The view is in a word line direction of memory cells 400, 410, 420 comprising a flat control gate and charge-trapping regions as a two-dimensional example of memory cells 400, 410, 420 in the memory cell array 126 of FIG. 1A. Charge-trapping memory can be used in NOR and NAND flash memory device. This technology uses an insulator such as an SiN film to store electrons, in contrast to a floating-gate MOSFET technology which uses a conductor such as doped polycrystalline silicon to store electrons. As an example, a word line 424 extends across NAND strings which include respective channel regions 406, 416, 426. Portions of the word line provide control gates 402, 412, 422. Below the word line is an IPD layer 428, charge-trapping layers 404, 414, 421, polysilicon layers 405, 415, 425, and tunneling layers 409, 407, 408. Each charge-trapping layer 404, 414, 421 extends continuously in a respective NAND string. The flat configuration of the control gate can be made thinner than a floating gate. Additionally, the memory cells can be placed closer together.

FIG. 4B illustrates a cross-sectional view of the structure of FIG. 4A along contact line connector 429. The NAND string 430 includes an SGS transistor 431, example memory cells 400, 433, . . . 435, and an SGD transistor 436. Passageways in the IPD layer 428 in the SGS and SGD transistors 431, 436 allow the control gate layers 402 and floating gate layers to communicate. The control gate 402 and floating gate layers may be polysilicon and the tunnel oxide layer may be silicon oxide, for instance. The IPD layer 428 can be a stack of nitrides (N) and oxides (0) such as in a N—O—N—O—N configuration.

The NAND string may be formed on a substrate which comprises a p-type substrate region 455, an n-type well 456 and a p-type well 457. N-type source/drain diffusion regions sd1, sd2, sd3, sd4, sd5, sd6 and sd7 are formed in the p-type well. A channel voltage, Vch, may be applied directly to the channel region of the substrate.

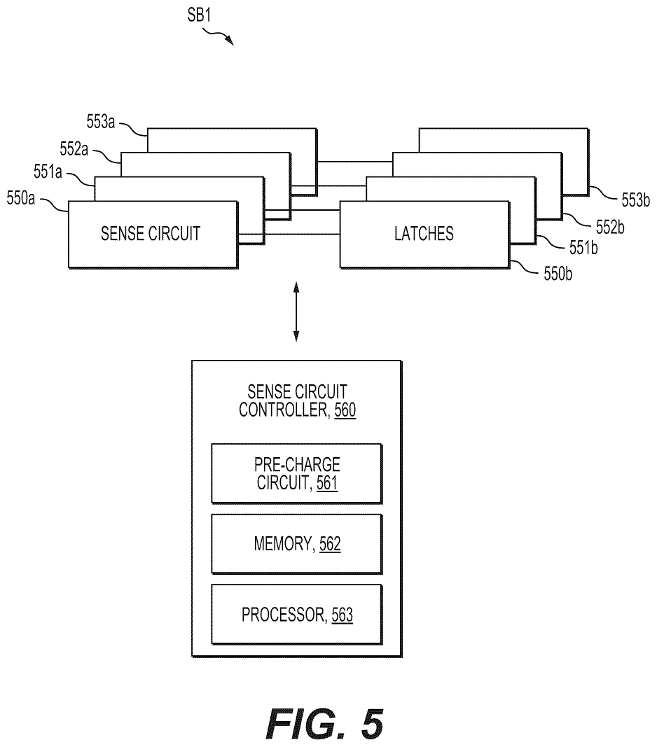

FIG. 5 illustrates an example block diagram of the sense block SB1 of FIG. 1A. In one approach, a sense block comprises multiple sense circuits. Each sense circuit is associated with data latches. For example, the example sense circuits 550a, 551a, 552a, and 553a are associated with the data latches 550b, 551b, 552b, and 553b, respectively. In one approach, different subsets of bit lines can be sensed using different respective sense blocks. This allows the processing load which is associated with the sense circuits to be divided up and handled by a respective processor in each sense block. For example, a sense circuit controller 560 in SB1 can communicate with the set of sense circuits and latches. The sense circuit controller 560 may include a pre-charge circuit 561 which provides a voltage to each sense circuit for setting a pre-charge voltage. In one possible approach, the voltage is provided to each sense circuit independently, e.g., via the data bus and a local bus. In another possible approach, a common voltage is provided to each sense circuit concurrently. The sense circuit controller 560 may also include a pre-charge circuit 561, a memory 562 and a processor 563. The memory 562 may store code which is executable by the processor to perform the functions described herein. These functions can include reading the latches 550b, 551b, 552b, 553b which are associated with the sense circuits 550a, 551a, 552a, 553a, setting bit values in the latches and providing voltages for setting pre-charge levels in sense nodes of the sense circuits 550a, 551a, 552a, 553a. Further example details of the sense circuit controller 560 and the sense circuits 550a, 551a, 552a, 553a are provided below.

In some embodiments, a memory cell may include a flag register that includes a set of latches storing flag bits. In some embodiments, a quantity of flag registers may correspond to a quantity of data states. In some embodiments, one or more flag registers may be used to control a type of verification technique used when verifying memory cells. In some embodiments, a flag bit's output may modify associated logic of the device, e.g., address decoding circuitry, such that a specified block of cells is selected. A bulk operation (e.g., an erase operation, etc.) may be carried out using the flags set in the flag register, or a combination of the flag register with the address register, as in implied addressing, or alternatively by straight addressing with the address register alone.

FIG. 6A is a perspective view of a set of blocks 600 in an example three-dimensional configuration of the memory array 126 of FIG. 1A. On the substrate are example blocks BLK0, BLK1, BLK2, BLK3 of memory cells (storage elements) and a peripheral area 604 with circuitry for use by the blocks BLK0, BLK1, BLK2, BLK3. For example, the circuitry can include voltage drivers 605 which can be connected to control gate layers of the blocks BLK0, BLK1, BLK2, BLK3. In one approach, control gate layers at a common height in the blocks BLK0, BLK1, BLK2, BLK3 are commonly driven. The substrate 601 can also carry circuitry under the blocks BLK0, BLK1, BLK2, BLK3, along with one or more lower metal layers which are patterned in conductive paths to carry signals of the circuitry. The blocks BLK0, BLK1, BLK2, BLK3 are formed in an intermediate region 602 of the memory device. In an upper region 603 of the memory device, one or more upper metal layers are patterned in conductive paths to carry signals of the circuitry. Each block BLK0, BLK1, BLK2, BLK3 comprises a stacked area of memory cells, where alternating levels of the stack represent word lines. In one possible approach, each block BLK0, BLK1, BLK2, BLK3 has opposing tiered sides from which vertical contacts extend upward to an upper metal layer to form connections to conductive paths. While four blocks BLK0, BLK1, BLK2, BLK3 are illustrated as an example, two or more blocks can be used, extending in the x-and/or y-directions.

In one possible approach, the length of the plane, in the x-direction, represents a direction in which signal paths to word lines extend in the one or more upper metal layers (a word line or SGD line direction), and the width of the plane, in the y-direction, represents a direction in which signal paths to bit lines extend in the one or more upper metal layers (a bit line direction). The z-direction represents a height of the memory device.

FIG. 6B illustrates an example cross-sectional view of a portion of one of the blocks BLK0, BLK1, BLK2, BLK3 of FIG. 6A. The block comprises a stack 610 of alternating conductive and dielectric layers. In this example, the conductive layers comprise two SGD layers, two SGS layers and four dummy word line layers DWLD0, DWLD1, DWLS0 and DWLS1, in addition to data word line layers (word lines) WLL0-WLL10. The dielectric layers are labelled as DL0-DL19. Further, regions of the stack 610 which comprise NAND strings NS1 and NS2 are illustrated. Each NAND string encompasses a memory hole 618, 619 which is filled with materials which form memory cells adjacent to the word lines. A region 622 of the stack 610 is shown in greater detail in FIG. 6D and is discussed in further detail below.

The 610 stack includes a substrate 611, an insulating film 612 on the substrate 611, and a portion of a source line SL. NS1 has a source-end 613 at a bottom 614 of the stack and a drain-end 615 at a top 616 of the stack 610. Contact line connectors (e.g., slits, such as metal-filled slits) 617, 620 may be provided periodically across the stack 610 as interconnects which extend through the stack 610, such as to connect the source line to a particular contact line above the stack 610. The contact line connectors 617, 620 may be used during the formation of the word lines and subsequently filled with metal. A portion of a bit line BL0 is also illustrated. A conductive via 621 connects the drain-end 615 to BL0.

FIG. 6C illustrates a plot of memory hole diameter in the stack of FIG. 6B. The vertical axis is aligned with the stack of FIG. 6B and illustrates a width (wMH), e.g., diameter, of the memory holes 618 and 619. The word line layers WLL0-WLL10 of FIG. 6A are repeated as an example and are at respective heights z0-z10 in the stack. In such a memory device, the memory holes which are etched through the stack have a very high aspect ratio. For example, a depth-to-diameter ratio of about 25-30 is common. The memory holes may have a circular cross-section. Due to the etching process, the memory hole width can vary along the length of the hole. Typically, the diameter becomes progressively smaller from the top to the bottom of the memory hole. That is, the memory holes are tapered, narrowing at the bottom of the stack. In some cases, a slight narrowing occurs at the top of the hole near the select gate so that the diameter becomes slightly wider before becoming progressively smaller from the top to the bottom of the memory hole.

Due to the non-uniformity in the width of the memory hole, the programming speed, including the program slope and erase speed of the memory cells can vary based on their position along the memory hole, e.g., based on their height in the stack. With a smaller diameter memory hole, the electric field across the tunnel oxide is relatively stronger, so that the programming and erase speed is relatively higher. One approach is to define groups of adjacent word lines for which the memory hole diameter is similar, e.g., within a defined range of diameter, and to apply an optimized verify scheme for each word line in a group. Different groups can have different optimized verify schemes.

FIG. 6D illustrates a close-up view of the region 622 of the stack 610 of FIG. 6B. Memory cells are formed at the different levels of the stack at the intersection of a word line layer and a memory hole. In this example, SGD transistors 680, 681 are provided above dummy memory cells 682, 683 and a data memory cell MC. A number of layers can be deposited along the sidewall (SW) of the memory hole 630 and/or within each word line layer, e.g., using atomic layer deposition. For example, each column (e.g., the pillar which is formed by the materials within a memory hole 630) can include a charge-trapping layer or film 663 such as SiN or other nitride, a tunneling layer 664, a polysilicon body or channel 665, and a dielectric core 666. A word line layer can include a blocking oxide/block high-k material 660, a metal barrier 661, and a conductive metal 662 such as Tungsten as a control gate. For example, control gates 690, 691, 692, 693, and 694 are provided. In this example, all of the layers except the metal are provided in the memory hole 630. In other approaches, some of the layers can be in the control gate layer. Additional pillars are similarly formed in the different memory holes. A pillar can form a columnar active area (AA) of a NAND string.

When a data memory cell MC is programmed, electrons are stored in a portion of the charge-trapping layer 663 which is associated with the memory cell MC. These electrons are drawn into the charge-trapping layer 663 from the channel 665, and through the tunneling layer 664. The Vth of a memory cell MC is increased in proportion to the amount of stored charge. During an erase operation, the electrons return to the channel 665.

Each of the memory holes 630 can be filled with a plurality of annular layers comprising a blocking oxide layer, a charge trapping layer 663, a tunneling layer 664 and a channel layer 665. A core region of each of the memory holes 630 is filled with a body material, and the plurality of annular layers are between the core region and the word line in each of the memory holes 630.

The NAND string can be considered to have a floating body channel 665 because the length of the channel 665 is not formed on a substrate. Further, the NAND string is provided by a plurality of word line layers above one another in a stack, and separated from one another by dielectric layers.

FIG. 6E depicts an example set of threshold voltage distributions for an eight-state memory device in which each storage element stores three bits of data. A first threshold voltage (Vth) distribution is provided for erased (Er-state) storage elements. Seven Vth distributions represent programmed states A through G. In one embodiment, the threshold voltages in the Er-state are negative and the threshold voltages in the A-G distributions are positive. However, all or a part of the threshold distribution in the Er-state may be positive. Also, all or a part of the threshold distribution of the A-state may be negative (likewise for other data states).

Read reference voltages, Vra, Vrb, Vrc, etc. are also provided for reading data from storage elements. By testing whether the threshold voltage of a given storage element is above or below Vra, Vrb Vrc, etc. the system can determine the state, e.g., programming condition, the storage element is in.

Further, verify reference voltages, Vva, Vvb Vvc, etc. are provided. When programming storage elements to the A-state, B-state, C-state, etc. the system will test whether those storage elements have a threshold voltage greater than or equal to Vva, Vvb Vvc, etc.

In one embodiment, known as full sequence programming, storage elements can be programmed from the erased state or Er-state directly to any of the programmed states A-G. For example, a population of storage elements to be programmed may first be erased so that all storage elements in the population are in the Er-state. A series of program pulses will then be used to program storage elements into their respective target states A-G. While some storage elements are being programmed from the Er-state to the A-state, other storage elements are being programmed from the Er-state to the B-state, etc.

There is a continuing need to develop programming techniques which tighten the Vt distributions of the programming data states in order to improve memory reliability but to do so in such a way that the improved reliability does not come at the expense of performance, i.e., programming time. One such programming technique is known as Quick Pass Write (QPW), which slows programming of the memory cells that pass a verify low VL voltage (e.g., verify low reference voltages VvAL, VvBL, VvCL of FIG. 6E). To slow programming, a QPW voltage is applied to the bit lines coupled to the memory cells that have passed the verify VL associated with a programmed data state (e.g., data state A) during the following Vpgm pulses. The QPW voltage applied to the bit lines of the memory cells that have passed the VL voltage reduces the voltage difference between the programming pulse Vpgm applied to the control gate of the selected word line and the voltage applied to the bit line coupled to the memory cell to slow programming of the memory cell. Any memory cell which passes a verify high VH voltage (e.g., verify high reference voltages VvA, VvB, VvC of FIG. 6E). is then locked down, or inhibited, from further programming.

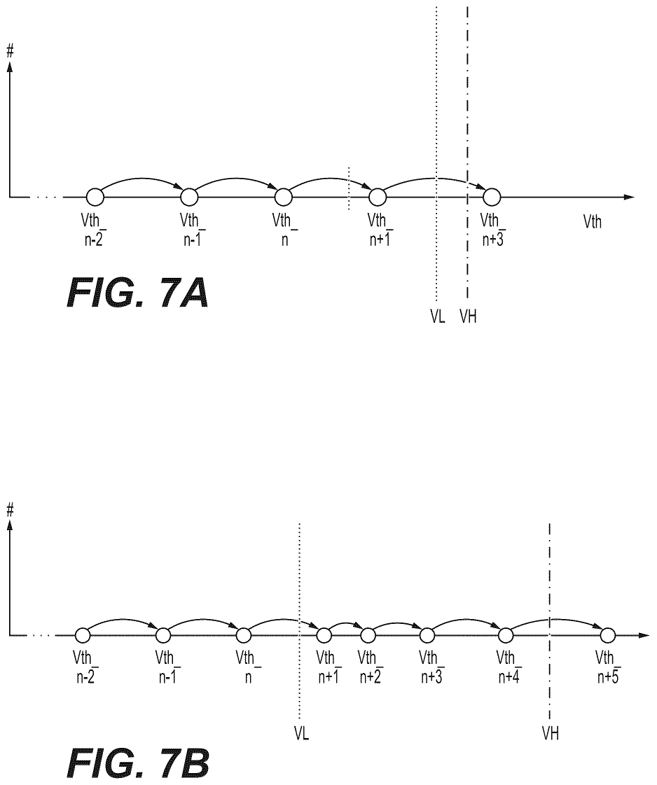

For QPW programming to be effective, the voltage gap between VL and VH should be maintained at an optimal level. If the voltage gap between VL and VH is too small, some memory cells below while close to the VL level may be directly programmed to over VH level, thus not going through slow-down process in QPW window, leading to over-program issue, as shown in the plot of FIG. 7A with each point identifying the threshold voltage of a particular memory cell following a Vpgm pulse. On the other hand, QPW programming only slows programming for a few (for example, two or three) program-verify iterations. Therefore, if the gap is too large, then some memory cells might get back to non-QPW programming speeds even within the QPW window between VL and VH, as shown in FIG. 7B. This also could lead to overprogramming.

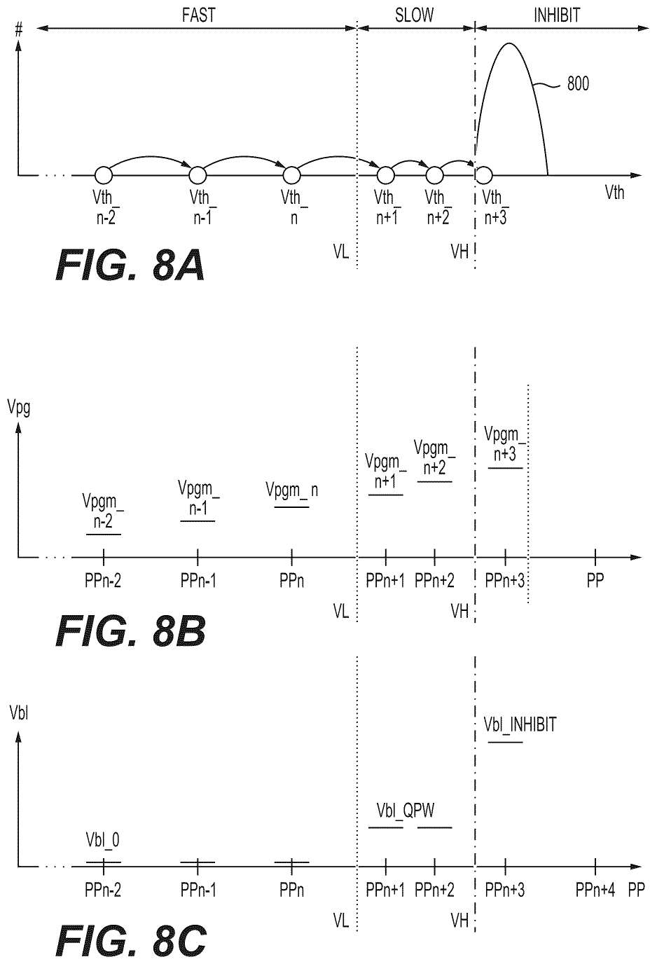

FIG. 8A depicts the progress of a Vth of a memory cell in a memory device where there is a proper gap between VL and VH with reference numeral 800 depicting a final Vth distribution of the memory cells programmed to this data state. In FIG. 8B, the horizontal axis depicts a program pulse number, and the vertical axis depicts a corresponding programming voltage Vpgm. In FIG. 8C, the horizontal axis depicts the program pulse number, and the vertical axis depicts a corresponding bit line voltage Vbl. In this example, fast programming occurs in the n−2, n−1, and n program-verify iterations, QPW programming occurs in the n+1 and n+2 program-verify iterations, and programming is inhibited from the n+3 program-verify iteration on. During fast programming, the bit line voltage Vbl is Vbl_0, which is very low, e.g., zero Volts (0 V). During QPW programming, the bit line voltage Vbl is Vbl_QPW, e.g., 0.6 V. During inhibit, the bit line voltage Vbl is Vbl_inhibit, e.g., 2.5 V.

In some programming operations, VL and VH are sensed by applying two separate verify pulses, one for VL and another for VH in each program-verify iteration. However, this can be a time consuming, thereby reducing the performance of the memory device. In other operations, VL and VH are sensed with a single verify pulse applied to the control gate of the selected word line but with different sensing time. In general, the sensing time for VH level is longer, and for VL level is shorter. Within the VL sensing time, if the sense node is fully discharged, then the Vt of the cell is judged as lower than VL, while if the sense node is not discharged sufficiently, the Vt of the cell is judged as higher than VL.

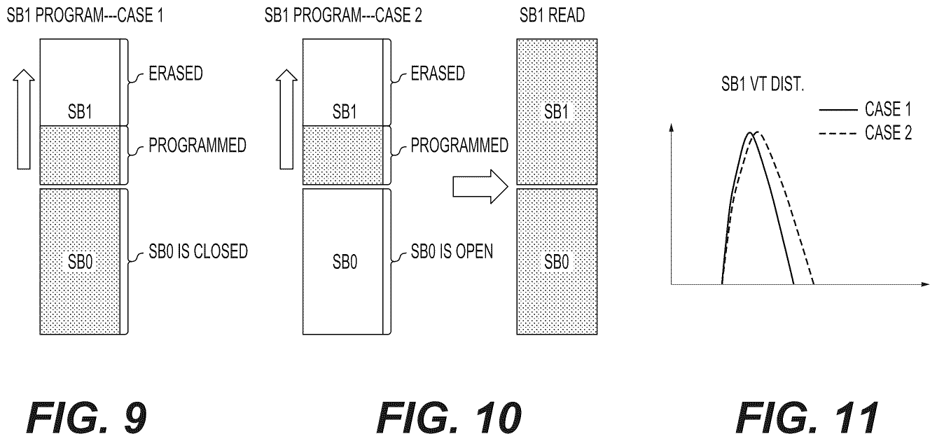

As discussed, a block of the memory cells may be formed into tiers, separated by a joint region and operable as sub-blocks (the memory apparatus or device is operable in a sub-block mode (SBM)). In such a sub-block mode, the sub-blocks may be programmed and read separately. Furthermore, the amount of the memory cells are programmed in sub-blocks during programming and later during a read operation can cause variation in the threshold voltage distribution for the memory cells. In the sub-block mode, there are many open block (i.e., the memory cells of the sub-block are not programmed and remain in the erased data state) scenarios. FIG. 9 shows two example sub-blocks SB0, SB1 with different amounts of the memory cells programmed. FIG. 10 shows two example sub-blocks SB0, SB1 with different amounts of the memory cells programmed along with a later read operation of one of the sub-blocks SB1 when the memory cells of both sub-blocks SB0, SB1 are completely programmed (i.e., closed sub-blocks). In the case shown in FIG. 9, taking the second sub-block SB1 as the example, the second sub-block SB1 will always programmed in some memory apparatuses when the unselected sub-block, the first sub-block SB0, is fully closed (i.e., the memory cells connected to all the word lines in the first sub-block SB0 are already programmed). As shown in FIG. 10, in another case in practice in some memory apparatuses is when the second sub-block SB1 is being programmed, the first sub-block SB0 can be a completely open block (e.g. all the memory cells connected to word lines in the first sub-block SB0 are in the erased state). However, in some memory apparatuses, the two cases will yield different threshold voltage Vt distributions, for example, with case 2 (FIG. 10), the state threshold voltage Vt width will be larger than the threshold voltage Vt width in case 1 (FIG. 9). FIG. 11 shows a plot of threshold voltage distributions for an example data state for the cases shown in FIGS. 9 and 10. It should be appreciated that case 2 (FIG. 10) is just an extreme case and typically the openness of the first sub-block SB0 during programming of the second sub-block SB1 can be random.

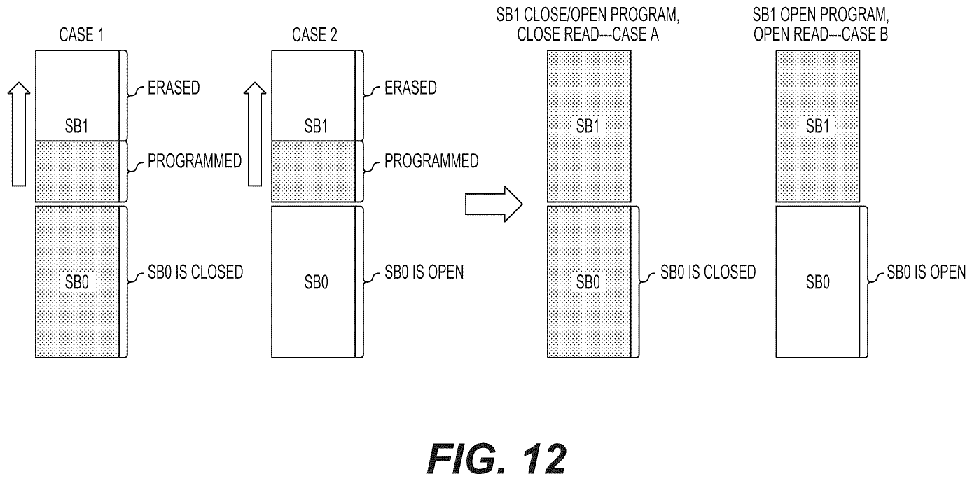

FIG. 12 shows the cases involving programming the two example sub-blocks with different amounts of the memory cells programmed of FIGS. 9 and 10 (cases 1 and 2) along with two cases of a later read operation of one of the sub-blocks with the memory cells of the first sub-block SB0 all programmed (case A) and all erased (case B) while the memory cells of the second sub-block SB1 are all programmed. As shown, for example, the selected sub-block can be programmed under two different cases, as shown in the upper left of FIG. 12. During read, another two cases can happen, the second sub-block SB1 is read in a read operation either when the first sub-block SB0 is fully closed (case A) or the first sub-block SB0 is fully open (case B).

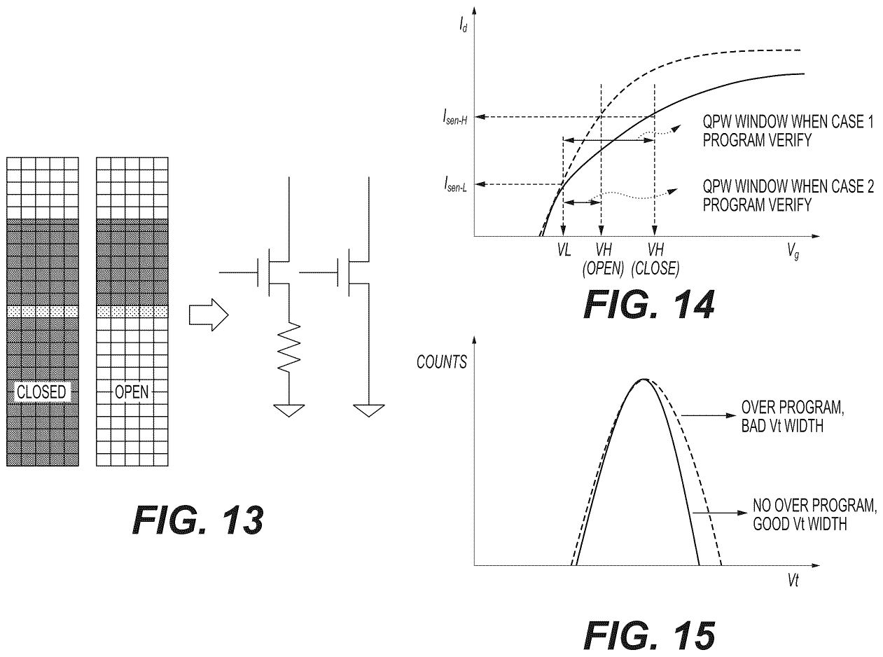

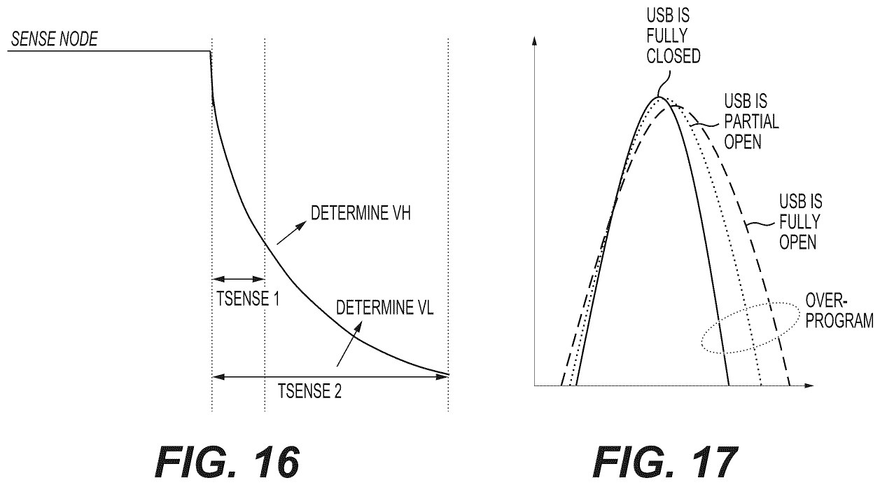

FIG. 13 shows an equivalent circuit diagrams of memory holes for the two programming cases of FIG. 12 (cases 1 and 2). FIG. 14 is a plot of drain current versus gate voltage during the verify portion or verify operation of a program operation for an example memory cell. FIG. 15 shows plots of the threshold voltage with and without over programming. The mechanism that case 1 and case 2 can yield different threshold voltage distribution or state width is because of the QPW and program verify. More specifically, case 1 and case 2 program verify will have different electric current in terms of the same data state. However, the QPW zone or window is usually optimized under one case only. FIG. 16 is a plot of a sensed voltage versus time during a verify operation without adjusting the sense time as described herein. When the QPW zone is optimized with USB closed, then this QPW zone will appear narrower with USB open, thus the state width gets widened (FIG. 15). FIG. 17 shows plots of the threshold voltage distribution when the USB is fully closed, partially open, and fully open with no adjustment of the sense time and illustrates over programming.

Consequently, described herein is a memory apparatus (e.g., memory device 100 of FIG. 1A) including memory cells (e.g., memory cell 310 of FIG. 3A, data memory cell MC of FIG. 6D) each connected to one of a plurality of word lines (e.g., word line layers WLL0-WLL10 in FIG. 6B). The memory cells are configured to retain a threshold voltage corresponding to a plurality of data states (e.g., threshold voltage distributions shown in FIG. 6E). The memory cells are disposed in memory holes (e.g., memory holes 618, 619 of FIG. 6B). The memory holes define channels (e.g., channel 665 of FIG. 6D) and extend vertically through a stack (e.g., stack 610 of FIG. 6B) of the plurality of word lines. Each of the memory holes is coupled to one of a plurality of bit lines (e.g., bit line BL0 of FIG. 6B). The memory cells form a block (e.g., BLK0, BLK1, BLK2, BLK3 of FIG. 6A) including a first sub-block SB0 (e.g., first sub-block SB0 of FIGS. 9, 10, and 12) and a second sub-block SB1 (e.g., second sub-block SB1 of FIGS. 9, 10, and 12) disposed vertically above the first sub-block SB0. The memory apparatus also includes a control circuit or means (e.g., one or any combination of memory controller 122 of FIG. 1A, control circuit 150 of FIG. 1B, and so forth). The control means is configured to apply each of a series of programming pulses of a program voltage (FIG. 8B) followed by verification pulses of a plurality of program verify voltages (e.g., verify low reference voltages VvAL, VvBL, VvCL and verify high reference voltages VvA, VvB, VvC of FIG. 6E) each associated with one of the plurality of data states to selected ones of the plurality of word lines of a selected one of the first sub-block SB0 or the second sub-block SB1 to program and verify the memory cells connected thereto during each of a plurality of program loops of a program operation. A channel current (e.g., Id of FIG. 14) flowing through the channels of the memory holes and sensed via the plurality of bit lines connected thereto for a sense time indicative of the threshold voltage of the memory cell being verified during each of the verification pulses. The control means is also configured to adjust the sense time based on an amount of the memory cells of an unselected one of the first sub-block SB0 or the second sub-block SB1 that are already programmed.

As discussed above for the QPW functionality, following each of the plurality of programming pulses and for each one of the memory cells, the control means is further configured to determine whether the threshold voltage of each of the memory cells detected exceeds a lower verify level VL (e.g., verify low reference voltages VvAL, VvBL, VvCL of FIG. 6E) and a higher verify level VH (e.g., verify high reference voltages VvA, VvB, VvC of FIG. 6E) of one of the plurality of data states targeted while applying one of a plurality of verify bit line voltages (FIG. 8C) to ones of the plurality of bit lines coupled to the memory cells being programmed. The one of the plurality of verify bit line voltages is selected based on the threshold voltage of the one of the memory cells relative to one of the lower verify level VL and the higher verify level VH. So, according to an additional aspect of the disclosure, the control means adjusts the sense time used while determining the threshold voltage of each of the memory cells detected exceeds the lower verify level VL based on the amount of the memory cells of the unselected one of the first sub-block SB0 or the second sub-block SB1 that are already programmed. In other words, the adjustment to the sense time is for the lower verify level VL.

According to other aspects, the control means is further configured to decrease the sense time as the amount of the memory cells of the unselected one of the first sub-block SB0 or the second sub-block SB1 that are already programmed increases. According to another aspect, the control means is further configured to adjust the sense time based on both the amount of the memory cells of the unselected one of the first sub-block SB0 or the second sub-block SB1 that are already programmed and which one of the plurality of data states targeted for the memory cells being verified.

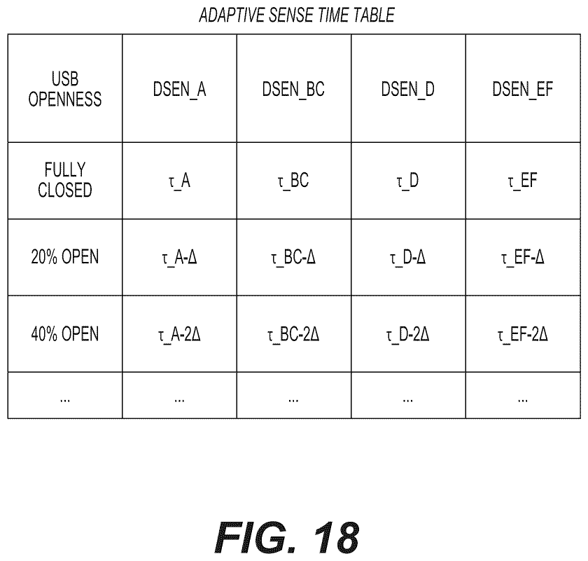

The amount of the memory cells of the unselected one of the first sub-block SB0 or the second sub-block SB1 that are already programmed can correspond with an openness of the unselected one of the first sub-block SB0 or the second sub-block SB1. As discussed above, each of the memory cells is configured to store three bits and the plurality of data states includes, in order of the threshold voltage increasing in magnitude, an erased data state (e.g., ERASE state of FIG. 6E), a first data state (e.g., A state of FIG. 6E), a second data state (e.g., B state of FIG. 6E), a third data state (e.g., C state of FIG. 6E), a fourth data state (e.g., D state of FIG. 6E), a fifth data state (e.g., E state of FIG. 6E), a sixth data state (e.g., F state of FIG. 6E), and a seventh data state (e.g., G state of FIG. 6E). So, according to an aspect, the memory apparatus stores a table with a plurality of predetermined sense times for each of a plurality of predetermined magnitudes of the openness of the unselected one of the first sub-block SB0 or the second sub-block SB1 and based on the one plurality of data states targeted for the memory cells being verified. FIG. 18 is an example table with the plurality of predetermined sense times for each of the plurality of predetermined magnitudes of the openness of the unselected one of the first sub-block SB0 or the second sub-block SB1 and based on the one plurality of data states targeted for the memory cells being verified. Such a table helps dynamically adjust the sense time (DSEN) to compensate the threshold voltage Vt distribution width widening due to the different openness of the unselected-sub-block discussed above with reference to FIGS. 9-15.

Accordingly, still referring to FIG. 18 and according to other aspects, the control means is further configured to use one of a first group (e.g., DSEN_A) of the plurality of predetermined sense times in response to the memory cells targeted for first data state being verified. The control means uses one of a second group (e.g., DSEN_BC) of the plurality of predetermined sense times in response to the memory cells of one of the second data state and the third data state being verified. In addition, the control means is configured to use one of a third group (e.g., DSEN_D) of the plurality of predetermined sense times in response to the memory cells targeted for the fourth data state being verified. The control means is also configured to use one of a fourth group (e.g., DSEN_EF) of the plurality of predetermined sense times in response to the memory cells of one of the fifth data state and the sixth data state being verified. According to further aspects of the disclosure, the control means is further configured to not adjust the sense time in response to substantially all of the memory cells of the unselected one of the first sub-block SB0 or the second sub-block SB1 being already programmed.

According to additional aspects, the memory apparatus further includes block openness data stored and updated in the memory apparatus and configured to track which of the plurality of word lines were last programmed in each of the first sub-block SB0 and the second sub-block SB1. In other words, openness information of the unselected sub-block can be tracked and supplied by the memory apparatus. Thus, the control means is further configured to determine the amount of the memory cells of the unselected one of the first sub-block SB0 or the second sub-block SB1 that are already programmed based on the block openness data before the program operation.

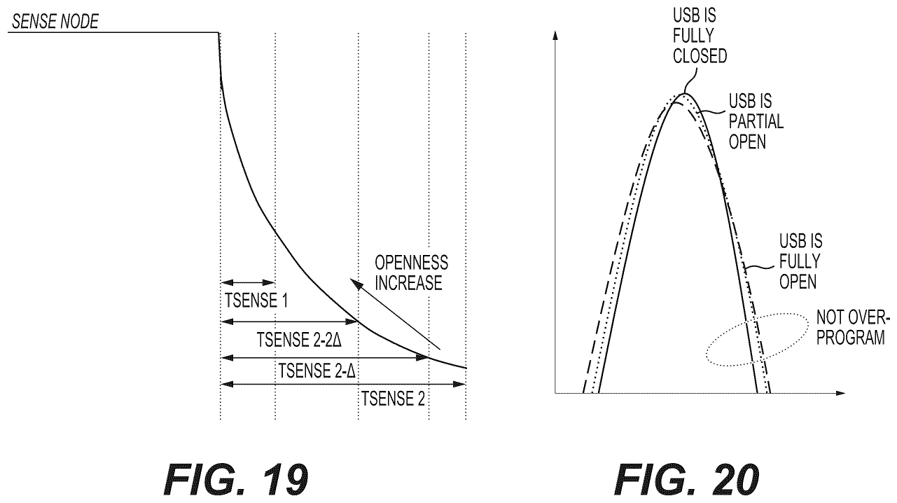

FIG. 19 is a plot of a sensed voltage versus time during a verify operation with the adjustment of the sense time as described herein. FIG. 20 shows plots of the threshold voltage distribution when the USB is fully closed, partially open, and fully open using the adjustment of the sense time as described herein and illustrates no over programming. So, the adjustment of the sense time described can effective narrow the state width and make open sub block operation in sub-block mode workable.

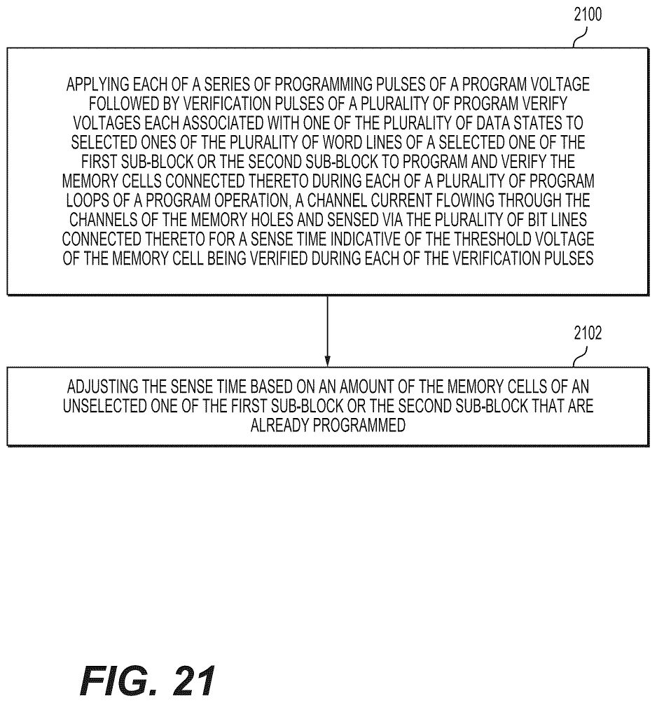

FIG. 21 illustrates steps of a method of operating a memory apparatus. As discussed above, the memory apparatus memory apparatus (e.g., memory device 100 of FIG. 1A) including memory cells (e.g., memory cell 310 of FIG. 3A, data memory cell MC of FIG. 6D) each connected to one of a plurality of word lines (e.g., word line layers WLL0-WLL10 in FIG. 6B). The memory cells are configured to retain a threshold voltage corresponding to a plurality of data states (e.g., threshold voltage distributions shown in FIG. 6E). The memory cells are disposed in memory holes (e.g., memory holes 618, 619 of FIG. 6B). The memory holes define channels (e.g., channel 665 of FIG. 6D) and extend vertically through a stack (e.g., stack 610 of FIG. 6B) of the plurality of word lines. Each of the memory holes is coupled to one of a plurality of bit lines (e.g., bit line BL0 of FIG. 6B). The memory cells form a block (e.g., BLK0, BLK1, BLK2, BLK3 of FIG. 6A) including a first sub-block SB0 (e.g., first sub-block SB0 of FIGS. 9, 10, and 12) and a second sub-block SB1 (e.g., second sub-block SB1 of FIGS. 9, 10, and 12) disposed vertically above the first sub-block SB 0. The method includes the step of 2100 applying each of a series of programming pulses (FIG. 8B) of a program voltage followed by verification pulses of a plurality of program verify voltages (e.g., verify low reference voltages VvAL, VvBL, VvCL and verify high reference voltages VvA, VvB, VvC of FIG. 6E) each associated with one of the plurality of data states to selected ones of the plurality of word lines of a selected one of the first sub-block SB0 or the second sub-block SB1 to program and verify the memory cells connected thereto during each of a plurality of program loops of a program operation. The channel current (Id of FIG. 14) flowing through the channels of the memory holes and sensed via the plurality of bit lines connected thereto for a sense time indicative of the threshold voltage of the memory cell being verified during each of the verification pulses. The method also includes the step of 2102 adjusting the sense time based on an amount of the memory cells of an unselected one of the first sub-block SB0 or the second sub-block SB1 that are already programmed.

For the QPW functionality discussed above, the method further includes the step of following each of the plurality of programming pulses and for each one of the memory cells, determining whether the threshold voltage of each of the memory cells detected exceeds a lower verify level VL (e.g., verify low reference voltages VvAL, VvBL, VvCL of FIG. 6E) and a higher verify level VH (e.g., verify high reference voltages VvA, VvB, VvC of FIG. 6E) of one of the plurality of data states targeted while applying one of a plurality of verify bit line voltages (FIG. 8C) to ones of the plurality of bit lines coupled to the memory cells being programmed. The one of the plurality of verify bit line voltages is selected based on the threshold voltage of the one of the memory cells relative to one of the lower verify level VL and the higher verify level VH. Therefore, according to an additional aspect of the disclosure, method includes the step of adjusting the sense time used while determining the threshold voltage of each of the memory cells detected exceeds the lower verify level VL based on the amount of the memory cells of the unselected one of the first sub-block SB0 or the second sub-block SB1 that are already programmed. In other words, the adjustment to the sense time is for the lower verify level VL.

According to other aspects, the method further includes the step of decreasing the sense time as the amount of the memory cells of the unselected one of the first sub-block SB0 or the second sub-block SB1 that are already programmed increases. According to another aspect, the method further includes the step of adjusting the sense time based on both the amount of the memory cells of the unselected one of the first sub-block SB0 or the second sub-block SB1 that are already programmed and which one of the plurality of data states targeted for the memory cells being verified.

Again, the amount of the memory cells of the unselected one of the first sub-block SB0 or the second sub-block SB1 that are already programmed can correspond with an openness of the unselected one of the first sub-block SB0 or the second sub-block SB1. As above, each of the memory cells may be configured to store three bits and the plurality of data states includes, in order of the threshold voltage increasing in magnitude, an erased data state (e.g., ERASE state of FIG. 6E), a first data state (e.g., A state of FIG. 6E), a second data state (e.g., B state of FIG. 6E), a third data state (e.g., C state of FIG. 6E), a fourth data state (e.g., D state of FIG. 6E), a fifth data state (e.g., E state of FIG. 6E), a sixth data state (e.g., F state of FIG. 6E), and a seventh data state (e.g., G state of FIG. 6E). Thus, according to an aspect, the memory apparatus stores a table with a plurality of predetermined sense times for each of a plurality of predetermined magnitudes of the openness of the unselected one of the first sub-block SB0 or the second sub-block SB1 and based on the one plurality of data states targeted for the memory cells being verified.

Referring back to FIG. 18 and according to other aspects, the method further includes the step of using one of a first group (e.g., DSEN_A) of the plurality of predetermined sense times in response to the memory cells targeted for first data state being verified. The method additionally includes the step of using one of a second group (e.g., DSEN_BC) of the plurality of predetermined sense times in response to the memory cells of one of the second data state and the third data state being verified. Furthermore, the method includes the step of using one of a third group (e.g., DSEN_D) of the plurality of predetermined sense times in response to the memory cells targeted for the fourth data state being verified. In addition, the method includes the step of using one of a fourth group (e.g., DSEN_EF) of the plurality of predetermined sense times in response to the memory cells of one of the fifth data state and the sixth data state being verified. According to further aspects of the disclosure, the method further includes the step of not adjusting the sense time in response to substantially all of the memory cells of the unselected one of the first sub-block SB0 or the second sub-block SB1 being already programmed.

Once again, according to additional aspects, the memory apparatus further includes block openness data stored and updated in the memory apparatus and configured to track which of the plurality of word lines were last programmed in each of the first sub-block SB0 and the second sub-block SB1. Therefore, the method further includes the step of determining the amount of the memory cells of the unselected one of the first sub-block SB0 or the second sub-block SB1 that are already programmed based on the block openness data before the program operation.

The foregoing detailed description of the invention has been presented for purposes of illustration and description. It is not intended to be exhaustive or to limit the invention to the precise form disclosed. Many modifications and variations are possible in light of the above teachings. The described embodiments were chosen in order to best explain the principles of the invention and its practical application, to thereby enable others skilled in the art to best utilize the invention in various embodiments and with various modifications as are suited to the particular use contemplated. It is intended that the scope of the invention be defined by the claims appended hereto.

What is claimed is:

1. A memory apparatus, comprising:
memory cells each connected to one of a plurality of word lines and configured to retain a threshold voltage corresponding to one of a plurality of data states, the memory cells disposed in memory holes defining channels and extending vertically through a stack of the plurality of word lines, each of the memory holes being coupled to one of a plurality of bit lines, the memory cells form a block including a first sub-block and a second sub-block disposed vertically above the first sub-block; and
a control means configured to:
apply each of a series of programming pulses of a program voltage followed by verification pulses of a plurality of program verify voltages each associated with one of the plurality of data states to selected ones of the plurality of word lines of a selected one of the first sub-block or the second sub-block to program and verify the memory cells connected thereto during each of a plurality of program loops of a program operation, a channel current flowing through the channels of the memory holes and sensed via the plurality of bit lines connected thereto for a sense time indicative of the threshold voltage of the memory cell being verified during each of the verification pulses, and
adjust the sense time based on an amount of the memory cells of an unselected one of the first sub-block or the second sub-block that are already programmed.

2. The memory apparatus as set forth in claim 1, wherein following each of the plurality of programming pulses and for each one of the memory cells, the control means is further configured to:
determine whether the threshold voltage of each of the memory cells detected exceeds a lower verify level and a higher verify level of one of the plurality of data states targeted while applying one of a plurality of verify bit line voltages to ones of the plurality of bit lines coupled to the memory cells being programmed, the one of the plurality of verify bit line voltages selected based on the threshold voltage of the one of the memory cells relative to one of the lower verify level and the higher verify level; and
adjust the sense time used while determining the threshold voltage of each of the memory cells detected exceeds the lower verify level based on the amount of the memory cells of the unselected one of the first sub-block or the second sub-block that are already programmed.

3. The memory apparatus as set forth in claim 1, wherein the control means is further configured to decrease the sense time as the amount of the memory cells of the unselected one of the first sub-block or the second sub-block that are already programmed increases.

4. The memory apparatus as set forth in claim 1, wherein the control means is further configured to adjust the sense time based on both the amount of the memory cells of the unselected one of the first sub-block or the second sub-block that are already programmed and which one of the plurality of data states targeted for the memory cells being verified.

5. The memory apparatus as set forth in claim 4, wherein the amount of the memory cells of the unselected one of the first sub-block or the second sub-block that are already programmed corresponds with an openness of the unselected one of the first sub-block or the second sub-block, each of the memory cells is configured to store three bits and the plurality of data states includes, in order of the threshold voltage increasing in magnitude, an erased data state and a first data state and a second data state and a third data state and a fourth data state and a fifth data state and a sixth data state and a seventh data state, the memory apparatus stores a table with a plurality of predetermined sense times for each of a plurality of predetermined magnitudes of the openness of the unselected one of the first sub-block or the second sub-block and based on the one plurality of data states targeted for the memory cells being verified, and the control means is further configured to:
use one of a first group of the plurality of predetermined sense times in response to the memory cells targeted for first data state being verified;
use one of a second group of the plurality of predetermined sense times in response to the memory cells of one of the second data state and the third data state being verified;
use one of a third group of the plurality of predetermined sense times in response to the memory cells targeted for the fourth data state being verified; and
use one of a fourth group of the plurality of predetermined sense times in response to the memory cells of one of the fifth data state and the sixth data state being verified.

6. The memory apparatus as set forth in claim 1, wherein the control means is further configured to not adjust the sense time in response to substantially all of the memory cells of the unselected one of the first sub-block or the second sub-block being already programmed.

7. The memory apparatus as set forth in claim 1, further including block openness data stored and updated in the memory apparatus and configured to track which of the plurality of word lines were last programmed in each of the first sub-block and the second sub-block and wherein the control means is further configured to determine the amount of the memory cells of the unselected one of the first sub-block or the second sub-block that are already programmed based on the block openness data before the program operation.

8. A controller in communication with a memory apparatus including memory cells each connected to one of a plurality of word lines and configured to retain a threshold voltage corresponding to one of a plurality of data states, the memory cells disposed in memory holes defining channels and extending vertically through a stack of the plurality of word lines, each of the memory holes being coupled to one of a plurality of bit lines, the memory cells form a block including a first sub-block and a second sub-block disposed vertically above the first sub-block, the controller configured to:
instruct the memory apparatus to apply each of a series of programming pulses of a program voltage followed by verification pulses of a plurality of program verify voltages each associated with one of the plurality of data states to selected ones of the plurality of word lines of a selected one of the first sub-block or the second sub-block to program and verify the memory cells connected thereto during each of a plurality of program loops of a program operation, a channel current flowing through the channels of the memory holes and sensed via the plurality of bit lines connected thereto for a sense time indicative of the threshold voltage of the memory cell being verified during each of the verification pulses; and
instruct the memory apparatus to adjust the sense time based on an amount of the memory cells of an unselected one of the first sub-block or the second sub-block that are already programmed.

9. The controller as set forth in claim 8, wherein following each of the plurality of programming pulses and for each one of the memory cells, the controller is further configured to:
instruct the memory apparatus to determine whether the threshold voltage of each of the memory cells detected exceeds a lower verify level and a higher verify level of one of the plurality of data states targeted while applying one of a plurality of verify bit line voltages to ones of the plurality of bit lines coupled to the memory cells being programmed, the one of the plurality of verify bit line voltages selected based on the threshold voltage of the one of the memory cells relative to one of the lower verify level and the higher verify level; and
adjust the sense time used while determining the threshold voltage of each of the memory cells detected exceeds the lower verify level based on the amount of the memory cells of the unselected one of the first sub-block or the second sub-block that are already programmed.

10. The controller as set forth in claim 8, wherein the controller is further configured to decrease the sense time as the amount of the memory cells of the unselected one of the first sub-block or the second sub-block that are already programmed increases.

11. The controller as set forth in claim 8, wherein the controller is further configured to adjust the sense time based on both the amount of the memory cells of the unselected one of the first sub-block or the second sub-block that are already programmed and which one of the plurality of data states targeted for the memory cells being verified.

12. The controller as set forth in claim 11, wherein the amount of the memory cells of the unselected one of the first sub-block or the second sub-block that are already programmed corresponds with an openness of the unselected one of the first sub-block or the second sub-block, each of the memory cells is configured to store three bits and the plurality of data states includes, in order of the threshold voltage increasing in magnitude, an erased data state and a first data state and a second data state and a third data state and a fourth data state and a fifth data state and a sixth data state and a seventh data state, the memory apparatus stores a table with a plurality of predetermined sense times for each of a plurality of predetermined magnitudes of the openness of the unselected one of the first sub-block or the second sub-block and based on the one plurality of data states targeted for the memory cells being verified, and the controller is further configured to:
use one of a first group of the plurality of predetermined sense times in response to the memory cells targeted for first data state being verified;
use one of a second group of the plurality of predetermined sense times in response to the memory cells of one of the second data state and the third data state being verified;
use one of a third group of the plurality of predetermined sense times in response to the memory cells targeted for the fourth data state being verified; and
use one of a fourth group of the plurality of predetermined sense times in response to the memory cells of one of the fifth data state and the sixth data state being verified.

13. The controller as set forth in claim 8, wherein the controller is further configured to not adjust the sense time in response to substantially all of the memory cells of the unselected one of the first sub-block or the second sub-block being already programmed.

14. A method of operating a memory apparatus including memory cells each connected to one of a plurality of word lines and configured to retain a threshold voltage corresponding to one of a plurality of data states, the memory cells disposed in memory holes defining channels and extending vertically through a stack of the plurality of word lines, each of the memory holes being coupled to one of a plurality of bit lines, the memory cells form a block including a first sub-block and a second sub-block disposed vertically above the first sub-block, the method comprising the steps of:
applying each of a series of programming pulses of a program voltage followed by verification pulses of a plurality of program verify voltages each associated with one of the plurality of data states to selected ones of the plurality of word lines of a selected one of the first sub-block or the second sub-block to program and verify the memory cells connected thereto during each of a plurality of program loops of a program operation, a channel current flowing through the channels of the memory holes and sensed via the plurality of bit lines connected thereto for a sense time indicative of the threshold voltage of the memory cell being verified during each of the verification pulses; and
adjusting the sense time based on an amount of the memory cells of an unselected one of the first sub-block or the second sub-block that are already programmed.

15. The method as set forth in claim 14, wherein following each of the plurality of programming pulses and for each one of the memory cells, the method further includes the steps of:
determining whether the threshold voltage of each of the memory cells detected exceeds a lower verify level and a higher verify level of one of the plurality of data states targeted while applying one of a plurality of verify bit line voltages to ones of the plurality of bit lines coupled to the memory cells being programmed, the one of the plurality of verify bit line voltages selected based on the threshold voltage of the one of the memory cells relative to one of the lower verify level and the higher verify level; and
adjusting the sense time used while determining the threshold voltage of each of the memory cells detected exceeds the lower verify level based on the amount of the memory cells of the unselected one of the first sub-block or the second sub-block that are already programmed.

16. The method as set forth in claim 14, further including the step of decreasing the sense time as the amount of the memory cells of the unselected one of the first sub-block or the second sub-block that are already programmed increases.

17. The method as set forth in claim 14, further including the step of adjusting the sense time based on both the amount of the memory cells of the unselected one of the first sub-block or the second sub-block that are already programmed and which one of the plurality of data states targeted for the memory cells being verified.

18. The method as set forth in claim 17, wherein the amount of the memory cells of the unselected one of the first sub-block or the second sub-block that are already programmed corresponds with an openness of the unselected one of the first sub-block or the second sub-block, each of the memory cells is configured to store three bits and the plurality of data states includes, in order of the threshold voltage increasing in magnitude, an erased data state and a first data state and a second data state and a third data state and a fourth data state and a fifth data state and a sixth data state and a seventh data state, the memory apparatus stores a table with a plurality of predetermined sense times for each of a plurality of predetermined magnitudes of the openness of the unselected one of the first sub-block or the second sub-block and based on the one plurality of data states targeted for the memory cells being verified, and the method further includes the steps of:
using one of a first group of the plurality of predetermined sense times in response to the memory cells targeted for first data state being verified;
using one of a second group of the plurality of predetermined sense times in response to the memory cells of one of the second data state and the third data state being verified;
using one of a third group of the plurality of predetermined sense times in response to the memory cells targeted for the fourth data state being verified; and
using one of a fourth group of the plurality of predetermined sense times in response to the memory cells of one of the fifth data state and the sixth data state being verified.

19. The method as set forth in claim 14, further including the step of not adjusting the sense time in response to substantially all of the memory cells of the unselected one of the first sub-block or the second sub-block being already programmed.

20. The method as set forth in claim 14, wherein the memory apparatus further includes block openness data stored and updated in the memory apparatus and configured to track which of the plurality of word lines were last programmed in each of the first sub-block and the second sub-block and the method further includes the step of determining the amount of the memory cells of the unselected one of the first sub-block or the second sub-block that are already programmed based on the block openness data before the program operation.
